(19) United States
(12) Patent Application Publication
(10) Pub. No.: US 2008/0165569 A1
(43) Pub. Date: Jul. 10, 2008

(54) Resistance Limited Phase Change Memory Material

(76) Inventors: Chieh-Fang Chen, Panchiao City (TW); Shih-Hung Chen, Elmsford, NY (US); Yi-Chou Chen, San Jose, CA (US); Thomas Happ, Tarrytown, NY (US); Chia Hua Ho, Guanxi Town (TW); Ming-Hsiang Hsueh, Hsinchu city (TW); Chung Hon Lam, Peekskill, NY (US); Hsiang-Lan Lung, Elmsford, NY (US); Jan Boris Philipp, Peekskill, NY (US); Simone Raoux, Santa Clara, CA (US)

Correspondence Address: Michael L. Wise;RYAN, MASON & LEWIS, LLP, 90 Forest Avenue, Locust Valley, NY, 11560, US

(21) Appl. No.: 11/619,625

(22) Filed: Jan. 4, 2007

(51) Int. Cl. G11C 11/00; H01L 21/06; H01L 21/00

(52) U.S. Cl. 365/163; 365/148; 438/102; 438/104; 257/E21.001; 257/E21.068

(57) ABSTRACT

A memory cell comprises a first electrode, a second electrode and a composite material. The composite material electrically couples the first electrode to the second electrode. Moreover, the composite material comprises a phase change material and a resistor material. At least a portion of the phase change material is operative to switch between a substantially crystalline phase and a substantially amorphous phase in response to an application of a switching signal to at least one of the first and second electrodes. In addition, the resistor material has a resistivity lower than that of the phase change material when the phase change material is in the substantially amorphous phase.

### FIELD OF THE INVENTION

The present invention is directed generally to memory circuitry and, more particularly, to phase change memories.

### BACKGROUND OF THE INVENTION

The possibility of using phase change materials (PCMs) in nonvolatile memory cells has recently gained momentum as more is learned about these materials and their integration into integrated circuits. When incorporated in a memory cell, for example, these materials may be toggled between higher and lower electrical resistivity phases by applying a pulse of electrical current (“switching current pulse”) to the memory cell which acts to heat the PCM. Applying a switching current pulse that results in the PCM heating above its crystallization temperature causes the PCM to achieve a relatively low resistivity crystalline phase. Applying a larger magnitude switching current pulse (often called a “RESET” current pulse), on the other hand, causes the PCM to melt and to enter a relatively high resistivity amorphous phase during the subsequent cooling. After writing to the memory cell in this way, the overall electrical resistance state of the given memory cell may be determined (i.e., read) by applying a low magnitude sensing voltage to the memory cell in order to determine its electrical resistance state. Presently, binary and ternary chalcogenide alloys such as doped SbTe and Ge₂Sb₂Te₅ (GST) are showing the greatest promise for use in practical PCM-based memory cells.

Notably, many PCM-based memory cells are capable of being reproducibly switched between greater than two resistance states by varying the magnitude of the switching current pulse. This phenomenon was reported in, for example, U.S. Pat. No. 5,296,716 to Ovshinsky et al., entitled “Electrically Erasable, Directly Overwritable, Multibit Single Cell Memory Elements and Arrays Fabricated Therefrom,” and may be attributable to placing differing portions of a given volume of PCM into crystalline and amorphous phases. Advantageously, such a dynamic frequently gives a PCM-based memory cell the ability to simultaneously store more than one bit of data. FIG. 1, for example, illustrates a simple, “pillar-like” memory cell 100 configured in four different memory states (labeled “00,” “01,” “10” and “11,” respectively). The memory cell comprises lower and upper electrodes, 110 and 120, respectively, and PCM material 130 between the electrodes. A dielectric material 140 surrounds the PCM. In the “00” memory state, the entire PCM volume is in the crystalline phase and the memory cell displays a relatively low overall resistance. However, when the memory cell is placed into the “01,” “10” and “11” memory states, increasingly larger portions of the PCM volume are configured into the amorphous phase. This causes the overall resistance of the memory cell to display progressively higher resistances, with the “11” memory state being the highest.

Nevertheless, despite their apparent advantages, a multibit PCM-based memory cell frequently displays an extremely high overall resistance when a portion of its PCM volume is in an amorphous phase. FIG. 2, for example, shows the simulated resistance, R_{READ}, of a pillar-like PCM-based memory cell similar to that shown in FIG. 1 as a function of the switching current pulse power, P_{RESET}. With the switching current pulse power less than about 0.35 mW, the whole of the PCM remains in its low resistivity crystalline phase. However, when the switching current pulse power is increased above this value, a portion of the PCM in the memory cell enters the amorphous phase and the memory cell resistance rises sharply by over six orders of magnitude. Unfortunately, as a result of these high resistance values, typically only a small current is detectible when reading the memory cell in one of these higher resistance states. As a result, the reading speed for the memory cell is adversely affected.

For the foregoing reasons, there is a need for a multibit PCM-based memory cell design that allows the incorporated PCM to be configured into a higher resistivity phase without causing the memory cell to have an extremely high overall resistance value and a relatively slow reading speed.

### SUMMARY OF THE INVENTION

Embodiments of the present invention address the above-identified needs by providing a multibit PCM-based memory cell design that allows the incorporated PCM to be configured into a higher resistivity phase without causing the memory cell to have an extremely high overall resistance value and a relatively slow reading speed.

In accordance with an aspect of the invention, a memory cell comprises a first electrode, a second electrode and a composite material. The composite material electrically couples the first electrode to the second electrode. Moreover, the composite material comprises a PCM and a resistor material. At least a portion of the PCM is operative to switch between a substantially crystalline phase and a substantially amorphous phase in response to an application of a switching signal to at least one of the first and second electrodes. In addition, the resistor material has a resistivity lower than that of the phase change material when the phase change material is in the substantially amorphous phase.

In accordance with an illustrative embodiment of the invention, a memory cell comprises a lower electrode and an upper electrode between which is disposed a composite material. The composite material comprises a PCM interspersed with a multiplicity of resistor clusters. At least a portion of the PCM is operative to switch between a lower resistivity crystalline phase and a higher resistivity amorphous phase in response to the passing of a pulse of current through the composite material. The resistor clusters, in turn, comprise a resistor material that has a lower resistivity than the PCM when the PCM is in its higher resistivity amorphous phase. Advantageously, when reading the memory cell having at least a portion of the PCM is in its higher resistivity amorphous phase, some of the read current passes through the resistor clusters. The overall resistance of the memory cell is thereby reduced by using the composite material rather than using a PCM alone. Reading speed may thereby be enhanced.

These and other features and advantages of the present invention will become apparent from the following detailed description which is to be read in conjunction with the accompanying drawings.

### BRIEF DESCRIPTION OF THE DRAWINGS

FIG. 1 shows sectional views of a conventional PCM-based memory cell in four different data storage states.

FIG. 2 shows a chart of read resistance as a function of reset power for a conventional PCM-based memory cell.

FIG. 3 shows a memory cell in accordance with a first illustrative embodiment of the invention.

FIG. 4 shows a sectional view of a memory cell in accordance with a second illustrative embodiment of the invention.

FIG. 5 shows a sectional view of a memory cell in accordance with a third illustrative embodiment of the invention.

FIG. 6 shows a sectional view of a memory cell in accordance with a fourth illustrative embodiment of the invention.

FIGS. 7A-7C show a first illustrative method for forming a memory cell in accordance with aspects of the invention.

FIGS. 8A-8F show a second illustrative method for forming a memory cell in accordance with aspects of the invention.

FIGS. 9A-9F show a third illustrative method for forming a memory cell in accordance with aspects of the invention.

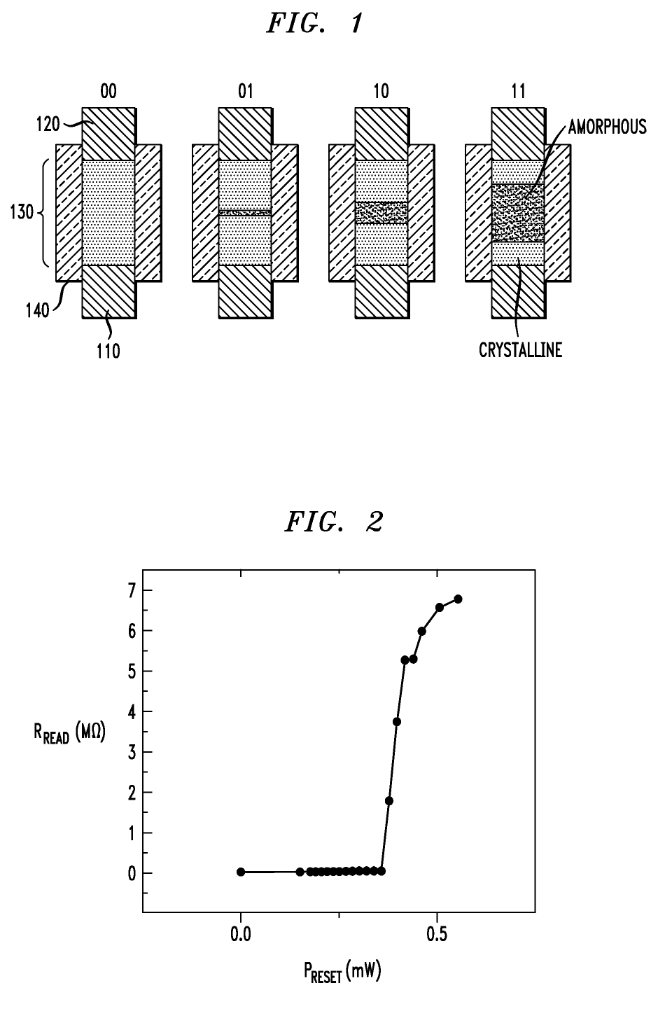

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

Particularly with respect to processing steps, it is emphasized that the descriptions provided herein are not intended to encompass all of the processing steps which may be required to successfully form a functional integrated circuit device. Rather, certain processing steps which are conventionally used in forming integrated circuit devices, such as, for example, wet cleaning and annealing steps, are purposefully not described herein for economy of description. However one skilled in the art will readily recognize those processing steps omitted from these generalized descriptions. Moreover, details of the processing steps used to fabricate such integrated circuit devices may be found in a number of publications, for example, S. Wolf and R. N. Tauber, Silicon Processing for the VLSI Era, Volume 1, Lattice Press, 1986 and S. M. Sze, VLSI Technology, Second Edition, McGraw-Hill, 1988.

The term “phase-change material” (PCM) as used herein is intended to encompass any material displaying more than one programmable electrical resistivity state for use in integrated circuits. It is recognized that this definition may encompass more materials than are customarily included within this term. PCMs as used herein comprise, for example, various chalcogenides and transition metal oxides and include, but are not limited to, doped or undoped GeSb, SbTe, Ge₂Sb₂Te₅ (GST), SrTiO₃, BaTiO₃, (Sr,Ba)TiO₃, SrZrO₃, In₂Se₃, Ca₂Nb₂O₇, (Pr,Ca)MnO₃, Ta₂)₅, NiOₓ and TiOₓ, as well as other suitable materials.

It should be noted that the figures are not drawn to scale. Moreover, the figures are simplified to illustrate aspects of the invention and, as a result, some elements required to form a functional semiconductor device may not be explicitly shown. These missing elements will be familiar to one skilled in the art.

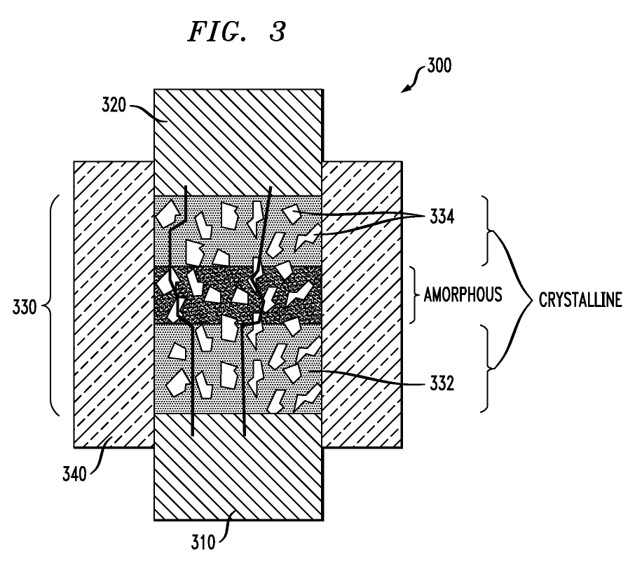

FIG. 3 shows a simplified sectional view of a memory cell 300 in accordance with an illustrative embodiment of the invention. The memory cell comprises a lower electrode 310 (e.g., tungsten or copper), an upper electrode 320 (e.g., tungsten or copper) and a composite material 330 that is disposed between the electrodes. These elements are configured to form a pillar-like arrangement, although other shapes are contemplated and would still come within the scope of the invention. A dielectric material 340 (e.g., silicon dioxide or silicon nitride) surrounds a portion of the composite material and provides isolation from other devices (not shown).

In accordance with aspects of the invention, the composite material 330 comprises a PCM 332 and a resistor material. The resistor material is in the form of discrete resistor clusters 334 that are dispersed throughout the PCM. Moreover, the resistor material forming the resistor clusters has a lower resistivity than the PCM when the PCM is in its substantially amorphous phase. The composition and formation of the PCM and resistor clusters will be described in greater detail below.

Storing data in the memory cell 300 comprises placing some fraction of the total volume of the PCM 332 into a higher resistivity amorphous phase while the remainder of the PCM remains in a lower resistivity crystalline phase. In this way, the method of writing to the memory cell 300 is similar to that used to write to a conventional multibit PCM-based memory cell like, for example, memory cell 100 shown in FIG. 1. Transitions between the resistivity states of the PCM are accomplished by heating the PCM by applying of a pulse of switching current between the lower electrode 310 and the upper electrode 320. This causes the PCM to heat up due to ohmic heating. Typically, the higher the magnitude of the switching current pulse, the greater the portion of the PCM that is placed into the higher resistivity amorphous phase and the higher the resultant overall resistance for the memory cell. In the particular memory cell configuration shown in FIG. 3, about 25% ofthe PCM is in the amorphous phase. Nevertheless, this figure merely illustrates the memory cell in a particular memory state. Smaller or larger portions of the PCM would occupy the amorphous phase when the memory cell is in a different memory state.

The duration of the switching current pulse is preferably between about 1 and about 500 nanoseconds and has a fast falling edge (i.e., less than about ten nanoseconds), although the invention is not limited to any particular duration and/or rise or fall time of the switching current pulse. The fast falling edge acts to freeze the PCM 332 in its current phase without allowing additional time for the bonds within the material to continue to rearrange.

After writing to the memory cell 300, reading the state of the memory cell may be accomplished by applying a sensing voltage to the memory cell, again via the lower and upper electrodes 310, 320. The sensing voltage is preferably of low enough magnitude to provide negligible ohmic heating in the PCM 332. Accordingly, the electrical resistance state of the memory cell may be determined in this manner without disturbing its written electrical resistance state. Data integrity is thereby maintained while reading the data.

Advantageously, the inclusion of the resistor clusters 334 in the composite material 330 substantially reduces the overall resistance of the memory cell 300 when some portion of the PCM 332 is in its amorphous phase. FIG. 3 displays two black lines which illustrate the path of read current through the memory cell 300. As indicated by these lines, the read current tends to travel through the resistor clusters to the greatest extent possible when the read current is passing through that portion of the composite material comprising PCM in its higher resistivity amorphous phase. This is the path of least resistance for the read current since, in accordance with an aspect of the invention, the resistivity of the resistor material is lower than that of the PCM in its amorphous phase. This routing of the read current through the resistor clusters lowers the overall resistance of the memory cell. The lowering of the resistance of the memory cell, in turn, facilitates faster reading speeds.

If the resistor material, moreover, has a resistivity higher than that of the PCM 332 in its crystalline phase, the read current will avoid the resistor clusters 334 in those portions of the composite material 330 comprising the PCM in its lower resistivity crystalline phase. This is the condition shown in FIG. 3. However, this second resistivity relationship is entirely optional for the implementation of the invention. It may, nevertheless, be preferable so that the majority of the switching current travels through the PCM during a write operation and efficient ohmic heating of the PCM is thereby achieved.

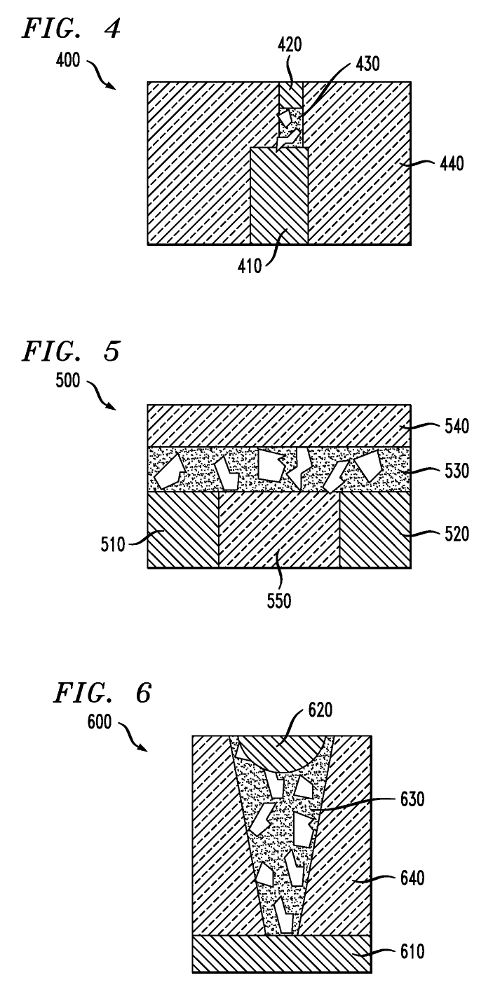

As stated above, the lower and upper electrodes 310, 320 and the composite material 330 in the memory cell 300 are formed into a pillar arrangement. Nonetheless, this is just one design contemplated for a memory cell in accordance with aspects of this invention. FIGS. 4-6 show other illustrative memory cell embodiments. The memory cell 400 in FIG. 4, for example, comprises a lower electrode 410, an upper electrode 420, composite material 430 and dielectric material 440. In this particular embodiment, the lower and upper electrodes and the composite material have a circular cross-section in a plane parallel to the interfaces of the composite material and the electrodes, but may also take on other cross-sectional shapes (e.g., square or rectangular). Notably, the composite material and the upper electrode are narrower than the bottom electrode. It may be advantageous to narrow the composite material in this way in order to increase the current density in the composite material when writing to the memory cell. This higher current density results in a greater amount of ohmic heating for a given switching current pulse magnitude.

Alternatively, a memory cell in accordance with aspects of the invention may appear like memory cell 500 shown in FIG. 5. This memory cell comprises left and right electrodes, 510 and 520, respectively, which are connected by a line of composite material 530. Upper and lower dielectric layers, 540 and 550, respectively, are disposed above and below the line of composite material. In this memory cell design, a switching current pulse applied between the left and right electrodes travels along the length of the line of composite material (i.e., from left to right in the figure). This configuration, in turn, allows the required magnitude of the switching current pulse to be tuned by modifying the thickness and width of the line of composite material, as well as by modifying the length of composite material through which the current must travel when going from one electrode to the other electrode.

As even another alternative, a memory cell may be configured like memory cell 600 shown in FIG. 6. This memory cell comprises a bottom electrode 610, top electrode 620, composite material 630 and dielectric material 640. In this particular embodiment, the composite material fills a trench formed in the dielectric material. This design may be advantageous by causing the bottom portion of the composite material (near the bottom of the trench) to have a higher current density than the other portions of the composite material (that near the top of the trench) when writing to the memory cell. The magnitude of the switching current pulse may thereby be tuned by changing the profile of the trench.

Generally, the choice of the particular resistor material in a given memory cell embodiment will depend on the choice of the associated PCM. As stated before, the resistivity of the resistor material will be lower than that of the PCM in its amorphous phase (and, optionally, higher than the PCM in its crystalline phase). GST in its amorphous phase typically has a resistivity of about one KΩ-cm, depending on how the GST is deposited and whether the GST is doped. Suitable resistor material may therefore comprise a myriad of metallic and semiconductor materials. Such materials will preferably be commonly used in semiconductor processing for ease of manufacture and will not interdiffuse into the PCM and cause the PCM properties to be degraded. Possible choices include, for example, tantalum nitride, tantalum silicon nitride, titanium nitride, tungsten or tungsten nitride.

Formation of the composite material may be accomplished using several different techniques, many of which are variations on semiconductor processing steps that will be familiar to one skilled in that art. Sputter deposition, for example, is one of the most widely used techniques for the fabrication of thin film structures on semiconductor wafers. It is usually carried out in diode plasma systems known as magnetrons, in which a target is sputtered by ion bombardment and emits atoms and molecules, which are then deposited on the wafer in the form of a thin film. Several such sputter deposition tools are commercially available from semiconductor tool vendors such as Applied Materials, Inc.® (Santa Clara, Calif., USA). GST sputter targets, moreover, are commonly available from a number of vendors such as Applied Material, Inc. and Canon Anelva Corp (Tokyo, Japan). The composition of a given sputter target, moreover, may be custom tailored for a particular application. A single sputter target, may, for example, comprise more than one type of material for deposition.

Accordingly, one method for depositing the composite material is to sputter the composite material using a mixed sputter target comprising both the PCM and the resistor material. Alternatively, the composite material may be formed using two sputter targets, one comprising the PCM and the other comprising the resistor material. The two sputter targets may then be alternated as the deposition progresses.

As even another alternative, sputter deposition or other deposition techniques may be used to deposit a PCM that is heavily doped with the chosen resistor material. If the concentration of the resistor material in the PCM is higher than the solubility level of the PCM, the resistor material will segregate out from the PCM and form the desired resistor clusters.

What is more, the composite material may be formed using pre-formed resistor clusters. Pre-formed nanometer sized resistor clusters (e.g., 3-10 nm in size) may, for example, be suspended in a solution and deposited by a conventional spin coating process. In spin coating, the solution is placed on the substrate as the substrate is rotated at high speed in order to spread the solution by centrifugal force. The solution may comprise, for example, a volatile alcohol that may be removed by evaporation after the spin coating process is completed.

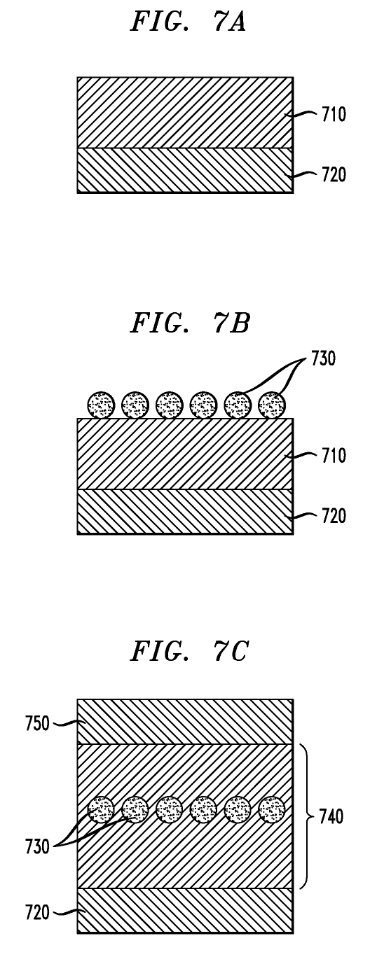

FIGS. 7A-7C illustrate such a deposition process. FIG. 7A shows a sectional view of a layer of PCM 710 deposited on a lower electrode 720. In FIG. 7B, resistor clusters 730 are deposited on the layer of PCM using a solution comprising pre-formed resistor clusters as described above. Finally, in FIG. 7C, additional PCM is conformally deposited on the film stack to complete composite material 740, and an upper electrode 750 is formed. While the composite material in FIG. 7C only comprises a single of layer of resistor clusters, this is merely for ease of understanding. It may be preferable in an actual device to form a composite material comprising several layers of resistor clusters by alternating several times between PCM deposition and resistor cluster deposition.

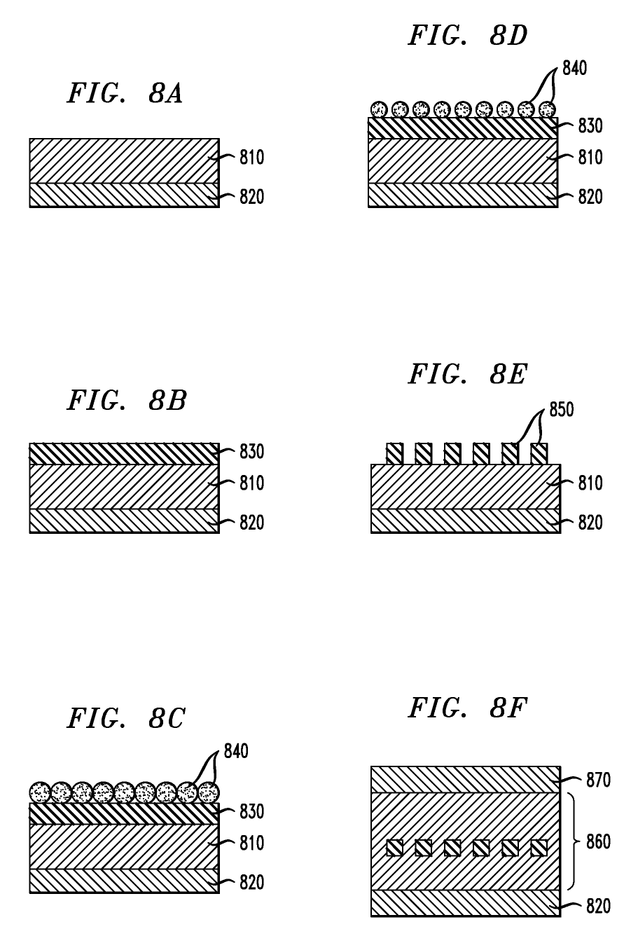

As even another alternative, nanometer sized particles (nanoparticles) of material other than the resistor material may be used in conjunction with largely conventional semiconductor processing techniques to form the composite material. FIGS. 8A-8F, for example, show an illustrative method for forming a memory cell using such nanoparticles. FIG. 8A shows a layer of PCM 810 formed on a lower electrode 820. In FIG. 8B, a layer of resistor material 830 is formed on the layer of PCM. Next, in FIG. 8C, a multiplicity of self-organized nanoparticles 840 are deposited on the resistor material. The nanoparticles may be deposited by, for example, a spin coating process similar to that described above or by several other deposition methods which will be familiar to one skilled in the art. In FIG. 8D, these nanoparticles are partially etched by an isotropic etch process (e.g., wet chemical etching) to adjust the size of the gap between the nanoparticles. In FIG. 8E, the reduced nanoparticles are used as an etch mask while an anisotropic etch process (e.g., reactive ion etching) is used to etch the resistor material to form discrete resistor clusters 850. The nanoparticles are also removed. Finally, in FIG. 8F, additional PCM is conformally deposited on the film stack to complete the composite material 860, and an upper electrode 870 is formed.

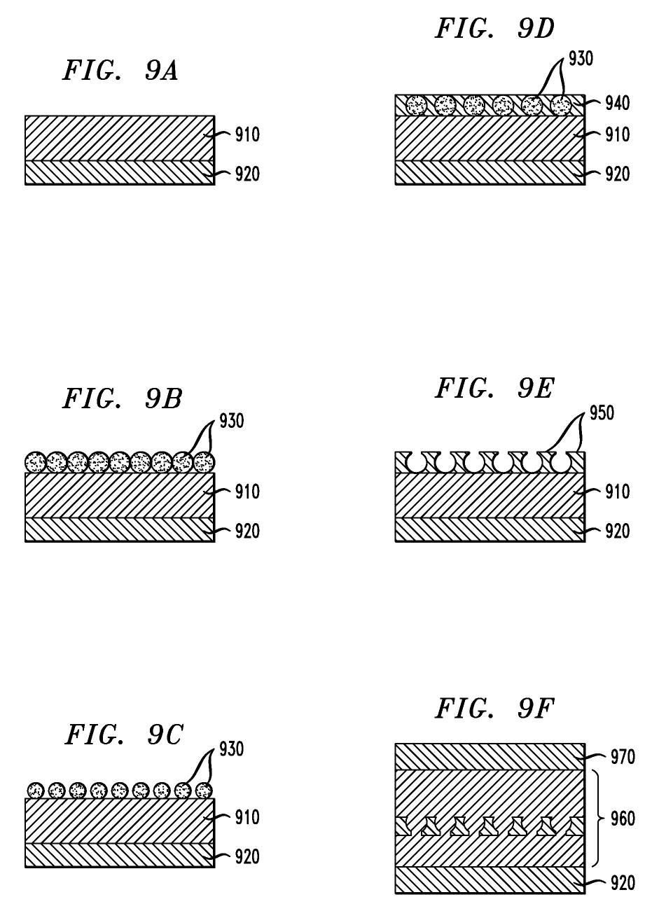

FIGS. 9A-9F go on to show a second illustrative method for forming a memory cell using nanoparticles. FIG. 9A shows a layer of PCM 910 formed on a lower electrode 920. In FIG.9B, a multiplicity of self-organized nanoparticles 930 are deposited on this PCM, again, for example, by spin coating. Next, in FIG. 9C, the nanoparticles are partially etched by, for example, a wet chemical etching process to adjust the size of the gap between the nanoparticles. In FIG. 9D, a resistor material 940 is deposited on the nanoparticles such that the tops of the nanoparticles remain exposed. Optionally, a chemical mechanical planarization process may be used to expose the tops of the nanoparticles after depositing the resistor material. Then, in FIG. 9E, the nanoparticles are removed by an isotropic etch process (e.g., a wet chemical etch) to form discrete resistor clusters 950. Finally, in FIG. 9F, additional PCM is deposited on the film stack to complete the composite material 960, and an upper electrode 970 is formed.

It should be noted that, while the composite materials 860 and 960 in the memory cells shown in FIG. 8F and FIG. 9F, respectively, each only comprise a single layer of resistor clusters, this is merely for ease of understanding. In an actual device, it may be preferable to form a composite material with several layers of such resistor clusters distributed throughout the composite material.

It should also be noted that the memory cells described above are part of the design for an integrated circuit chip. The chip design is created in a graphical computer programming language, and is stored in a computer storage medium (such as a disk, tape, physical hard drive or virtual hard drive such as in a storage access network). If the designer does not fabricate chips or photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are formed on a wafer. The photolithographic masks are utilized to define areas of the wafer (and/or the layers thereon) to be etched or otherwise processed.

The resulting integrated circuit chips may be distributed by the fabricator in raw wafer form (i.e., as a single wafer that has multiple unpackaged chips), as a bare die, or in packaged form. In the latter case, the chip is mounted in a single chip package (e.g., plastic carrier with leads that are affixed to a motherboard or other higher level carrier) or in a multichip package (e.g., ceramic carrier that has either or both surface interconnections or buried interconnections). In any case, the chip is then integrated with other chips, discrete circuit elements, and/or other signal processing devices as part of either an intermediate product (e.g., motherboard) or an end product. The end product may be any product that includes integrated circuit chips, ranging from toys and other low-end applications to advanced computer products having a display, a keyboard or other input device, and a central processor.

Although illustrative embodiments of the present invention have been described herein with reference to the accompanying figures, it is to be understood that the invention is not limited to those precise embodiments, and that various other changes and modifications may be made to these embodiments by one skilled in the art without departing from the scope of the appended claims.

What is claimed is:

1. A memory cell comprising:
a first electrode and a second electrode;
a composite material, the composite material electrically coupling the first electrode to the second electrode and comprising a phase change material and a resistor material;
wherein at least a portion of the phase change material is operative to switch between a substantially crystalline phase and a substantially amorphous phase in response to an application of a switching signal to at least one of the first and second electrodes; and
wherein the resistor material has a resistivity lower than that of the phase change material when the phase change material is in the substantially amorphous phase.

2. The memory cell of claim 1, wherein the memory cell is operative to simultaneously store more than one bit of information.

3. The memory cell of claim 1, wherein the resistor material has a resistivity higher than that of the phase change material when the phase change material is in the substantially crystalline phase.

4. The memory cell of claim 1, wherein the resistor material is arranged in a plurality of discrete clusters.

5. The memory cell of claim 1, wherein the resistor material comprises a metal or a semiconductor, or a combination thereof.

6. The memory cell of claim 1, wherein the resistor material comprises tantalum nitride, tantalum silicon nitride, titanium nitride, tungsten or tungsten nitride, or a combination thereof.

7. The memory cell of claim 1, wherein the phase change material comprises germanium, antimony, sulfur, indium, selenium or tellurium, or a combination thereof.

8. The memory cell of claim 1, wherein the phase change material comprises a ternary alloy comprising germanium, antimony and tellurium.

9. The memory cell of claim 1, wherein the switching signal is a pulse of electrical current with a duration of between about 1 and about 500 nanoseconds.

10. A method of forming a memory cell, the method comprising the steps of:
forming a first electrode and a second electrode;
forming a composite material, the composite material electrically coupling the first electrode to the second electrode and comprising a phase change material and a resistor material;
wherein at least a portion of the phase change material is operative to switch between a substantially crystalline phase and a substantially amorphous phase in response to an application of a switching signal to at least one of the first and second electrodes; and
wherein the resistor material has a resistivity lower than that of the phase change material when the phase change material is in the substantially amorphous phase.

11. The method of claim 10, wherein the step of forming the composite material comprises using nanoparticles as an etch mask.

12. The method of claim 10, wherein the step of forming the composite material comprises sputter deposition with a sputter target comprising the phase change material and the resistor material.

13. The method of claim 10, wherein the step of forming the composite material comprises sputter deposition with a first sputter target comprising the phase change material and a second sputter target comprising the resistor material.

14. The method of claim 10, wherein the step of forming the composite material comprises doping the phase change material with the resistor material.

15. An integrated circuit comprising one or more memory cells, at least one of the one or more memory cells comprising:
a first electrode and a second electrode;
a composite material, the composite material electrically coupling the first electrode to the second electrode and comprising a phase change material and a resistor material;
wherein at least a portion of the phase change material is operative to switch between a substantially crystalline phase and a substantially amorphous phase in response to an application of a switching signal to at least one of the first and second electrodes; and
wherein the resistor material has a resistivity lower than that of the phase change material when the phase change material is in the substantially amorphous phase.

16. The integrated circuit of claim 15, wherein the integrated circuit comprises nonvolatile memory circuitry.

17. The integrated circuit of claim 15, wherein the integrated circuit comprises a random access memory.

18. The integrated circuit of claim 15, wherein the at least one of the one or more memory cells is operative to simultaneously store more than one bit of information.

19. The integrated circuit of claim 15, wherein the resistor material has a resistivity higher than that of the phase change material when the phase change material is in the substantially crystalline phase.

20. The integrated circuit of claim 15, wherein the resistor material is arranged in a plurality of discrete clusters.
